(19) United States
(12) Patent Application Publication
(10) Pub. No.: US 2011/0241920 A1
(43) Pub. Date: Oct. 6, 2011

(54) RESISTANCE-TYPE DIGITAL-TO-ANALOG CONVERTER

(75) Inventor: GOROU MORI, Osaka (JP)

(73) Assignee: PANASONIC CORPORATION, Osaka (JP)

(21) Appl. No.: 13/159,698

(22) Filed: Jun. 14, 2011

Related U.S. Application Data
(63) Continuation of application No. PCT/JP2009/006975, filed on Dec. 17, 2009.

(30) Foreign Application Priority Data
May 27, 2009 (JP) 2009-127645

(51) Int. Cl. H03M 1/80

(52) U.S. Cl. 341/153

(57) ABSTRACT

Provided is a resistive digital-to-analog converter capable of reducing a digital-to-analog conversion error caused by a change of the on-resistance of a transistor. On-resistance correcting PMOS transistors Q2 to Q2^{N}−1 or on-resistance correcting NMOS transistors Q2′ to Q2^{N}−1′ are respectively connected in parallel to at least one of switching MOS transistors Q1 and Q1′ in each of switch circuits S1 to S2^{N}−1. Each of the on-resistance correcting PMOS transistors and the on-resistance correcting NMOS transistors is connected to correct the change of the on-resistance occurring with a change of an analog signal caused by a change of a multi-bit digital input signal. The on-resistance correcting PMOS transistors Q2 to Q2^{N}−1 or the on-resistance correcting NMOS transistors Q2′ to Q2^{N}−1′ are switched on or off in conjunction with switching of the switching MOS transistors Q1 and Q1′ according to the change of the digital input signal.

This is a continuation of International Application PCT/JP2009/006975, with an international filing date of Dec. 17, 2009.

### TECHNICAL FIELD

The present invention relates to a resistive digital-to-analog converter that converts a digital signal to an analog signal.

### BACKGROUND ART

An N-bit resistive digital-to-analog converter such as shown in FIG. 2 has been used as a high-precision digital-to-analog converter.

Such a resistive digital-to-analog converter includes a resistor network 2A and a switch circuit group 2B, and converts an N-bit digital signal to an analog signal.

The resistor network 2A includes 2^{N}−1 resistors R having the same resistance (the resistance is also represented by a reference sign R for the sake of convenience). One end of each of the 2^{N}−1 resistors R is connected in common to an analog output terminal Aₒᵤₜ for outputting an analog output signal generated after conversion.

The switch circuit group 2B includes 2^{N}−1 switch circuits S1 to S2^{N}−1. Each of the switch circuits S1 to S2^{N}−1 is a CMOS inverter circuit having the same structure in which a switching PMOS transistor Q1 and a switching NMOS transistor Q1′ are connected in series.

Specifically, a gate of the switching PMOS transistor Q1 and a gate of the switching NMOS transistor Q1′ are connected in common to an switching control end into which each of digital signals D1 to D2^{N}−1 is input. A source of the switching PMOS transistor Q1 in each of the switch circuits S1 to S2^{N}−1 is connected to a higher reference potential V, for conversion. On the other hand, a source of the switching NMOS transistor Q1′ in each of the switch circuits S1 to S2^{N}−1 is connected to a lower reference potential V_{b} for conversion. A drain of the switching PMOS transistor Q1 and a drain of the switching NMOS transistor Q1′ are connected in common to an output end X of each of the switch circuits S1 to S2^{N}−1. Each output end X is connected to one end of the resistor R having the resistance R in the resistor network 2A. As described above, the other end of the resistor R is connected to the analog output terminal Aₒᵤₜ.

Here, a potential difference between (i) the higher reference potential Vₜ to which the source of the switching PMOS transistor Q1 in each of the switch circuits S1 to S2^{N}−1 is connected and (ii) the lower reference potential V_{b} to which the source of the switching NMOS transistor Q1′ in each of the switch circuits S1 to S2^{N}−1 is connected is equal to the voltage of the analog output signal at full scale.

In the switch circuits S1 to S2^{N}−1 having the structure as shown in FIG. 2, when a level of each of the digital signals D1 to D2^{N}−1 input into the switching control end of a corresponding switch circuit becomes high enough to show a logical value “1”, the switching NMOS transistor Q1′ in the corresponding switch circuit is switched into a conducting state, and the lower reference potential V_{b} is output to the output end X. On the other hand, when the level of each of the digital signals D1 to D2^{N}−1 becomes low enough to show a logical value “0”, the switching PMOS transistor Q1 in the corresponding switch circuit is switched into the conducting state, and the higher reference potential Vₜ is output to the output end X.

In a case where any digital signal is to be converted to an analog signal, a value obtained by converting the digital signal to a decimal number is used as a data input value d. When the digital signals D1 to Dd each showing the logical value “0” are input, the switching PMOS transistor Q1 in each of the switch circuits S1 to Sd is switched into the conducting state. Also, when the digital signals Dd+1 to D2^{N}−1 each showing the logical value “1” are input, the switching NMOS transistors Q1′ in each of the switch circuits Sd+1 to S2^{N}−1 is switched into the conducting state.

As described above, by providing one of the higher reference potential Vₜ and the lower reference potential V_{b} to the resistor network 2A via the switch circuits S1 to S2^{N}−1, an analog output signal Aₒᵤₜ that is represented by the following equation (1) and weighed for each input of the digital signal is obtained.

$$\begin{matrix}[ Equation 1 ] & \\ {A}_{out ( d )} = ( {V}_{t} - {V}_{b} ) \times \frac{d}{{2}^{N} - 1} & ( 1 )\end{matrix}$$

### CITATION LIST

### Patent Literature

[Patent Literature 1]
Japanese Patent Application Publication No. 11-127080

### SUMMARY OF INVENTION

### Technical Problem

In the conventional resistive digital-to-analog converter as shown in FIG. 2, on-resistance r_{p(d)} of the switching PMOS transistor Q1 and on-resistance r_{n(d)} of the switching NMOS transistor Q1′ in each of the switch circuits S1 to S2^{N}−1 are connected to the resistor R included in the resistor network 2A in series. When the on-resistance is taken into account, the analog output signal Aₒᵤₜ is represented by the following equation (2).

$$\begin{matrix}[ Equation 2 ] & \\ {A}_{out ( d )} = ( {V}_{t} - {V}_{b} ) \times \frac{d}{\frac{R + {r}_{p ( d )}}{R + {r}_{n ( d )}} \times ( {2}^{N} - 1 - d ) + d} & ( 2 )\end{matrix}$$

In the equation (2), if the on-resistance r_{n(d)} of the switching NMOS transistor Q1′ and the on-resistance r_{p(d)} of the switching PMOS transistor Q1 are the same for a given data input value d, the analog output voltage Aₒᵤₜ is represented by the equation (1).

In reality, however, the on-resistance r_{n(d)} and r_{p(d)} changes depending on the data input value d as shown in FIG. 3. The change of the on-resistance is caused for the following reason. The voltage at the analog output terminal Aₒᵤₜ changes depending on the data input value d. Following the change in voltage at the analog output terminal Aₒᵤₜ, a voltage Vₓ at a common drain connection point X in each switch circuit fluctuates a little.

A dependence of the on-resistance r_{n(d)} of the switching NMOS transistor on the voltage Vₓ is represented by the following equation (3). In the following equation (3), reference sighs L, μₙ, cₒₓ, W, and Vₜₕ represent a gate length, an electron mobility, a gate capacitance per unit area, a gate width, and a threshold voltage of the NMOS transistor, respectively.

$$\begin{matrix}[ Equation 3 ] & \\ {r}_{n ( d )} = \frac{L}{{μ}_{n} {c}_{ox} W} \times \frac{{V}_{t} - {V}_{b} - {V}_{th} + {V}_{x ( d )} - {V}_{b}}{{( {V}_{t} - {V}_{b} - {V}_{th} )}^{2} - {( {V}_{x ( d )} - {V}_{b} )}^{2}} & ( 3 )\end{matrix}$$

Normally, a second part of denominator (V_{x(d)}−V_{b})² is small enough to be negligible compared with a first part of the denominator (Vₜ−V_{b}−Vₜₕ)². Therefore, the equation (3) may be approximated as shown in the following equation (4).

$$\begin{matrix}[ Equation 4 ] & \\ {r}_{n ( d )} ≅ \frac{L}{{μ}_{n} {{c}_{ox} ( {V}_{t} - {V}_{b} - {V}_{th} )}^{2}} \times \frac{{V}_{t} - 2 {V}_{b} - {V}_{th} + {V}_{x ( d )}}{W} & ( 4 )\end{matrix}$$

The equation (4) shows that the on-resistance r_{n(d)} of the switching NMOS transistor changes linearly depending on the voltage V_{x(d)} at the common drain connection point X. Since the voltage V_{x(d)} monotonically increases for the data input value d, the on-resistance r_{n(d)} also monotonically increases for the data input value d.

The on-resistance r_{p(d)} of the switching PMOS transistor shows an opposite behavior to the on-resistance r_{n(d)} of the switching NMOS transistor. Therefore, the on-resistance r_{p(d)} monotonically decreases for the data input value d. This is also shown in FIG. 3.

FIG. 4 shows an example of a digital-to-analog conversion error resulting from the change of the on-resistance of the MOS transistor described above. As can be seen from FIG. 4, the digital-to-analog conversion error is caused by the change of the on-resistance of the MOS transistor.

Also, as can be seen from the equation (4), the on-resistance of the MOS transistor is a function of the higher reference potential Vₜ and the lower reference potential V_{b}. Each of the higher reference potential Vₜ and the lower reference potential V_{b} is required to be set to an optimum level according to an application of the digital-to-analog converter. Therefore, it is desirable that each reference potential be variable.

However, the on-resistance of the MOS transistor changes when the reference potential is changed, and as a result, the digital-to-analog conversion error is caused. As described in Patent Literature 1, the above-mentioned problem is solved by using a method for maintaining the on-resistance of the MOS transistor constant against the change in reference potential. On the other hand, the on-resistance of the MOS transistor changes depending on the voltage V_{x(d)} at the common drain connection point X, i.e., the on-resistance of the MOS transistor changes with the change of an analog signal caused by the change of a multi-bit digital input signal. As for a problem of the digital-to-analog conversion error resulting from the above-mentioned change, there are still no methods for precisely reducing the digital-to-analog conversion error.

The present invention aims to provide a resistive digital-to-analog converter that is capable of reducing the digital-to-analog conversion error caused by the change of the on-resistance of the MOS transistor, which occurs with the change of an analog signal caused by the change of a multi-bit digital input signal.

### Solution to Problem

In order to solve the above-mentioned problem, the resistive digital-to-analog converter of the present invention is a resistive digital-to-analog converter that converts a multi-bit digital input signal to an analog signal, comprising: a resistor network that includes a plurality of resistors having the same resistance and outputs the analog signal from a common connection point to which one end of each of the plurality of resistors is connected in common; and a switch circuit group that includes a plurality of switch circuits each corresponding to a different one of the plurality of resistors and providing one of a higher reference potential and a lower reference potential for conversion to the other end of the corresponding resistor according to a level of each bit of the multi-bit digital input signal, wherein each switch circuit includes (i) a first switching MOS transistor that is connected to the other end of the corresponding resistor and a higher reference potential point at one end and the other end thereof, respectively, (ii) a second switching MOS transistor that is connected to the other end of the corresponding resistor and a lower reference potential point at one end and the other end thereof, respectively and (iii) an on-resistance correcting MOS transistor connected in parallel to at least one of the first and second switching MOS transistors such that a change of on-resistance, which occurs with a change of the analog signal caused by a change of the multi-bit digital input signal, is corrected.

With this structure, each switch circuit includes the on-resistance correcting MOS transistor connected in parallel to at least one of the first and second switching MOS transistors such that the change of on-resistance, which occurs with the change of the analog signal caused by the change of the multi-bit digital input signal, is corrected. By utilizing the on-resistance of the on-resistance correcting MOS transistor, the change of the on-resistance of the first and second switching MOS transistors is corrected. As a result, it becomes possible to reduce the digital-to-analog conversion error caused by the change of the on-resistance of the first and second MOS transistors, which is caused by the change in voltage of an analog signal.

When the resistive digital-to-analog converter having the above-mentioned structure is a first resistive digital-to-analog converter in which the on-resistance correcting MOS transistor is connected only in parallel to the first switching MOS transistor in each switch circuit, it is preferable that the on-resistance correcting MOS transistor is switched on or off according to a value of the multi-bit digital input signal so that, when the value of the multi-bit digital input signal indicates given data, combined parallel on-resistance of the first switching MOS transistor and the on-resistance correcting MOS transistor is equal to on-resistance of the second switching MOS transistor.

With this structure, the on-resistance correcting MOS transistor is switched on or off according to the value of the multi-bit digital input signal so that, when the value of the multi-bit digital input signal indicates given data, the combined parallel on-resistance of the first switching MOS transistor and the on-resistance correcting MOS transistor is equal to the on-resistance of the second switching MOS transistor. As a result, the digital-to-analog conversion error is sufficiently reduced.

When the resistive digital-to-analog converter having the above-mentioned structure is a second resistive digital-to-analog converter in which the on-resistance correcting MOS transistor is connected only in parallel to the second switching MOS transistor in each switch circuit, it is preferable that the on-resistance correcting MOS transistor is switched on or off according to a value of the multi-bit digital input signal so that, when the value of the multi-bit digital input signal indicates given data, combined parallel on-resistance of the second switching MOS transistor and the on-resistance correcting MOS transistor is equal to on-resistance of the first switching MOS transistor.

With this structure, the on-resistance correcting MOS transistor is switched on or off according to the value of the multi-bit digital input signal so that, when the value of the multi-bit digital input signal indicates given data, the combined parallel on-resistance of the second switching MOS transistor and the on-resistance correcting MOS transistor is equal to the on-resistance of the first switching MOS transistor. As a result, the digital-to-analog conversion error is sufficiently reduced.

Furthermore, when the resistive digital-to-analog converter having the above-mentioned structure is a third resistive digital-to-analog converter in which the on-resistance correcting MOS transistor includes a first on-resistance correcting MOS transistor connected in parallel to the first switching MOS transistor in each switch circuit, and a second on-resistance correcting MOS transistor connected in parallel to the second switching MOS transistor in each switch circuit, it is preferable that each of the first and second on-resistance correcting MOS transistors is switched on or off according to a value of the multi-bit digital input signal so that, when the value of the multi-bit digital input signal indicates given data, combined parallel on-resistance of the first switching MOS transistor and the first on-resistance correcting MOS transistor is equal to combined parallel on-resistance of the second switching MOS transistor and the second on-resistance correcting MOS transistor.

With this structure, each of the first and second on-resistance correcting MOS transistors is switched on or off according to the value of the multi-bit digital input signal so that, when the value of the multi-bit digital input signal indicates given data, the combined parallel on-resistance of the first switching MOS transistor and the first on-resistance correcting MOS transistor is equal to the combined parallel on-resistance of the second switching MOS transistor and the second on-resistance correcting MOS transistor. As a result, the digital-to-analog conversion error is sufficiently reduced.

In the structure of the first resistive digital-to-analog converter, it is preferable that as a bit order corresponding to each switch circuit increases, the switch circuit includes fewer on-resistance correcting MOS transistors connected in parallel to the first switching MOS transistor.

With this structure, as a bit order corresponding to a switch circuit increases, the switch circuit includes fewer on-resistance correcting MOS transistors connected in parallel to the first switching MOS transistor. Therefore, the on-resistance of the first switching MOS transistor that decreases proportionally for the data input value can be the same as the on-resistance of the second switching MOS transistor that increases proportionally for the data input value. As a result, the digital-to-analog conversion error is sufficiently reduced. In addition, flicker noise in the first switching MOS transistor is lower than that in the second switching MOS transistor. Therefore, the first resistive digital-to-analog converter is higher than the second or third resistive digital-to-analog converter in output SNR.

In the structure of the second resistive digital-to-analog converter, it is preferable that as a bit order corresponding to each switch circuit increases, the switch circuit includes more on-resistance correcting MOS transistors connected in parallel to the second switching MOS transistor.

With this structure, as a bit order corresponding to a switch circuit increases, the switch circuit includes more on-resistance correcting MOS transistors connected in parallel to the second switching MOS transistor. Therefore, the on-resistance of the second switching MOS transistor that increases proportionally for the data input value can be the same as the on-resistance of the first switching MOS transistor that decreases proportionally for the data input value. As a result, the digital-to-analog conversion error is sufficiently reduced. In addition, the on-resistance of the second switching MOS transistor is lower than that of the first switching MOS transistor. Therefore, the second resistive digital-to-analog converter can use an on-resistance correcting MOS transistor that is smaller in size than that used by the first or third resistive digital-to-analog converter, and thus a circuit area is reduced.

In the structure of the third resistive digital-to-analog converter, it is preferable that as a bit order corresponding to each switch circuit increases, the switch circuit includes fewer first on-resistance correcting MOS transistors connected in parallel to the first switching MOS transistor, and as a bit order corresponding to each switch circuit increases, the switch circuit includes more second on-resistance correcting MOS transistors connected in parallel to the second switching MOS transistor.

With this structure, as a bit order corresponding to a switch circuit increases, the switch circuit includes more second on-resistance correcting MOS transistors connected in parallel to the second switching MOS transistor. Therefore, the on-resistance of the second switching MOS transistor that increases proportionally for the data input value can be the same as the on-resistance of the first switching MOS transistor that decreases proportionally for the data input value. As a result, the digital-to-analog conversion error is sufficiently reduced. In addition, with the combination use of the first and second on-resistance correcting MOS transistors, the third resistive digital-to-analog converter corrects the on-resistance more precisely than the first or second resistive digital-to-analog converter, although the circuit area and the noise increase.

In the first resistive digital-to-analog converter, it is preferable that, for each switch circuit in which the first switching MOS transistor is switched on when the value of the multi-bit digital input signal indicates given data, the number of the on-resistance correcting MOS transistors that are switched on is the same.

With this structure, for each switch circuit in which the first switching MOS transistor is switched on when the value of the multi-bit digital input signal indicates the given data, the combined parallel on-resistance of the first switching MOS transistor and the on-resistance correcting MOS transistors connected in parallel to the first switching MOS transistor can be the same. As a result, the on-resistance is precisely corrected.

Also, in the second resistive digital-to-analog converter, it is preferable that, for each switch circuit in which the second switching MOS transistor is switched on when the value of the multi-bit digital input signal indicates given data, the number of the on-resistance correcting MOS transistors that are switched on is the same.

With this structure, for each switch circuit in which the second switching MOS transistor is switched on when the value of the multi-bit digital input signal indicates the given data, the combined parallel on-resistance of the second switching MOS transistor and the on-resistance correcting MOS transistors connected in parallel to the second switching MOS transistor can be the same. As a result, the on-resistance is precisely corrected.

Also, in the third resistive digital-to-analog converter, it is preferable that for each switch circuit in which the first switching MOS transistor is switched on when the value of the multi-bit digital input signal indicates given data, the number of the first on-resistance correcting MOS transistors that are switched on is the same, and, for each switch circuit in which the second switching MOS transistor is switched on when the value of the multi-bit digital input signal indicates given data, the number of the second on-resistance correcting MOS transistors that are switched on is the same.

With this structure, for each switch circuit in which the first switching MOS transistor is switched on when the value of the multi-bit digital input signal indicates the given data, the combined parallel on-resistance of the first switching MOS transistor and the first on-resistance correcting MOS transistors connected in parallel to the first switching MOS transistor can be the same. Also, for each switch circuit in which the second switching MOS transistor is switched on when the value of the multi-bit digital input signal indicates the given data, the combined parallel on-resistance of the second switching MOS transistor and the second on-resistance correcting MOS transistors connected in parallel to the second switching MOS transistor can be the same. As a result, the on-resistance is precisely corrected.

### Advantageous Effects of Invention

As set forth the above, the resistive digital-to-analog converter of the present invention reduces the digital-to-analog conversion error in the following manner. When the on-resistance of the first and second switching MOS transistors changes depending on a digital input value, the on-resistance correcting MOS transistor is connected in parallel to at least one of the first and second switching MOS transistors. Then, the on-resistance correcting MOS transistor is switched on or off so that on-resistance of the first switching MOS transistor (PMOS transistor) is equal to on-resistance of the second switching MOS transistor (NMOS transistor) when given data is input.

### BRIEF DESCRIPTION OF DRAWINGS

FIG. 1 is a circuit diagram illustrating an operation principle of a resistive digital-to-analog converter of the present invention.

FIG. 2 is a circuit diagram showing a structure of a conventional resistive digital-to-analog converter.

FIG. 3 is a characteristic chart showing changes of on-resistance of a switch circuit in the conventional resistive digital-to-analog converter.

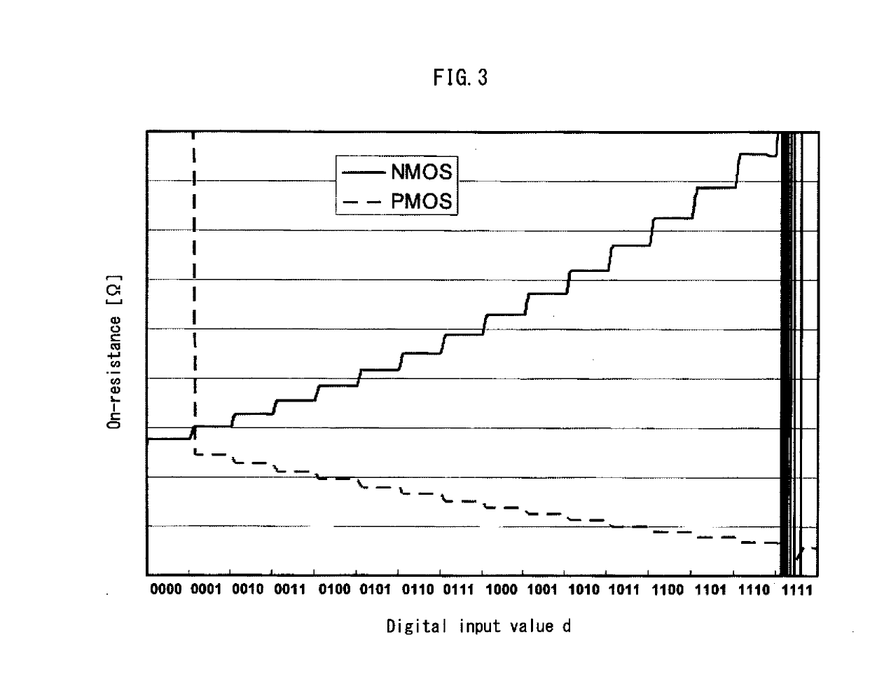

FIG. 4 is a characteristic chart showing a digital-to-analog conversion error caused in the conventional resistive digital-to-analog converter.

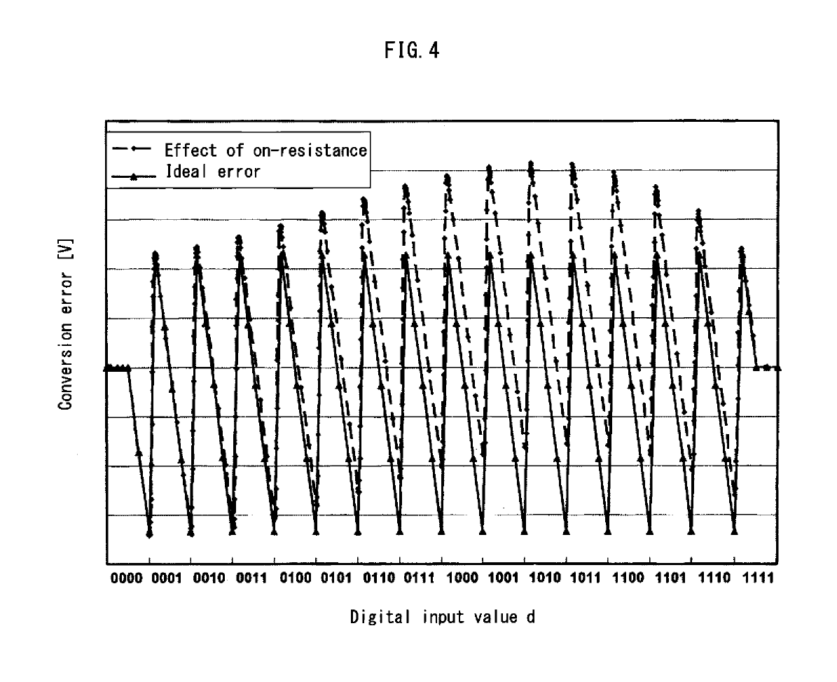

FIG. 5 is a circuit diagram showing a structure of the resistive digital-to-analog converter in embodiment 1 of the present invention.

FIG. 6 is a timing chart showing each data input value in the circuit diagram in embodiment 1 of the present invention.

FIG. 7 is a characteristic chart showing changes of on-resistance of a switch circuit in embodiment 1 of the present invention.

FIG. 8 is a characteristic chart showing a digital-to-analog conversion error in embodiment 1 of the present invention.

### DESCRIPTION OF EMBODIMENTS

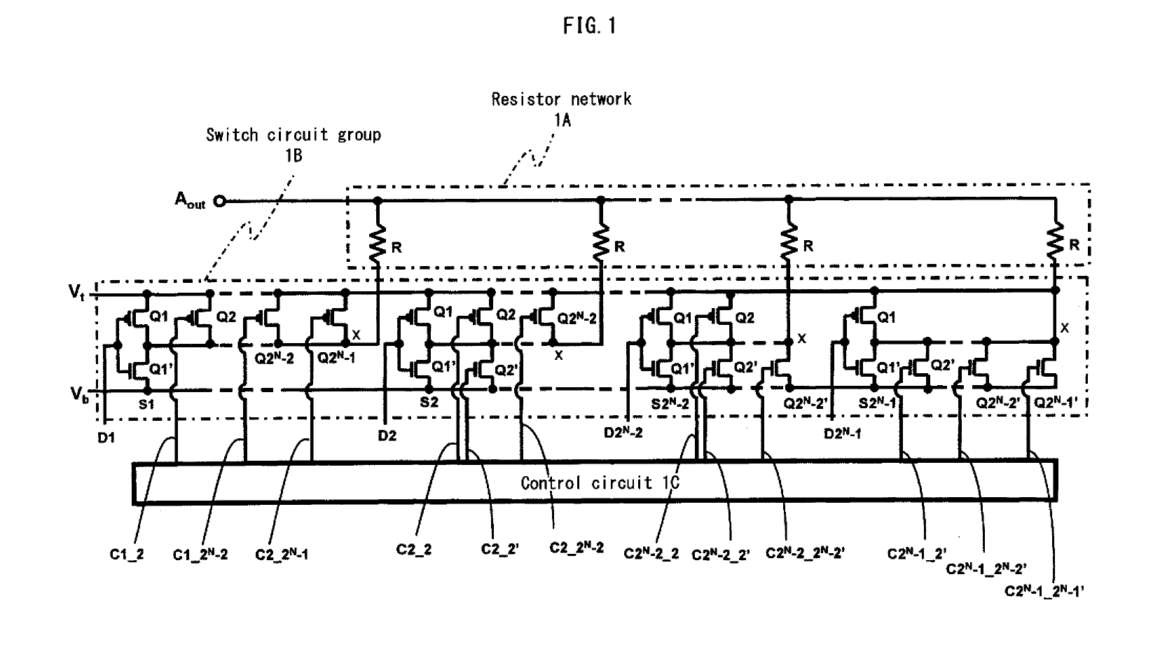

First, the following describes an operation principle of a resistive digital-to-analog converter of the present invention with reference to FIG. 1.

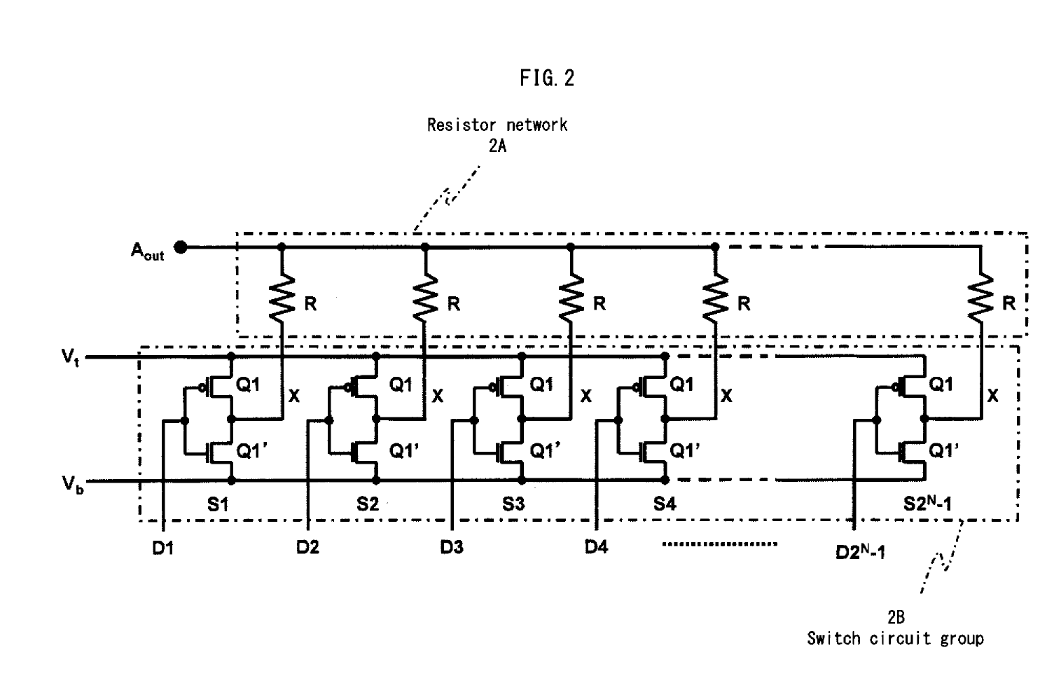

FIG. 1 is a diagram illustrating a principle of the present invention. The resistive digital-to-analog converter includes a resistor network 1A, a switch circuit group 1B, and a control circuit 1C. The resistive digital-to-analog converter differs from the conventional resistive digital-to-analog converter shown in FIG. 2 in its switch circuit group 1B and control circuit 1C.

In order to adjust on-resistance of a switching PMOS transistor Q1 and on-resistance of a switching NMOS transistor Q1′ in each of the switch circuits S1 to S2^{N}−1 based on a control signal, on-resistance correcting NMOS transistors Q2′ to Q2^{N}−1′ are connected in parallel to the switching NMOS transistor Q1′ in each of the switch circuits S1 to S2^{N}−1 included in the switch circuit group 1B. Specifically, a drain terminal of each of the on-resistance correcting NMOS transistors Q2′ to Q2^{N}−1, is connected to a corresponding output terminal X of each of the switch circuits S1 to S2^{N}−1. On the other hand, a source terminal is connected to the lower reference potential V_{b}.

Alternatively, on-resistance correcting PMOS transistors Q2 to Q2^{N}−1 are connected in parallel to the switching PMOS transistor Q1 in each of the switch circuits S1 to S2^{N}−1 included in the switch circuit group 1B. Specifically, a drain terminal of each of the on-resistance correcting PMOS transistors Q2 to Q2^{N}−1 is connected to a corresponding output terminal X of each of the switch circuits S1 to S2^{N}−1. On the other hand, a source terminal is connected to the higher reference potential Vₜ.

Here, the resistive digital-to-analog converter may have a structure in which the on-resistance correcting NMOS transistors Q2′ to Q2^{N}−1′ are connected in parallel to the switching NMOS transistor Q1′, and also the on-resistance correcting PMOS transistors Q2 to Q2^{N}−1 are connected in parallel to the switching PMOS transistor Q1.

Output signals (control signals) C1_2 to C1_2^{N}−1, C2_2 to C2_2^{N}−2, . . . , and C2^{N}-2_2 are output from the control circuit 1C, and input to respective gates of the on-resistance correcting PMOS transistors Q2 to Q2^{N}−1. Also, output signals (control signals) C2_2′, . . . , C2^{N}−2_2′ to C2^{N}−2_2^{N}−2′, and C2^{N}−1_2′ to C2^{N}−1_2^{N}−1′ are output from the control circuit 1C, and input to respective gates of the on-resistance correcting NMOS transistors Q2′ to Q2^{N}−1′.

As a bit order corresponding to a switch circuit increases from the switch circuits S2 to S2^{N}−1, the switch circuit includes more on-resistance correcting NMOS transistors connected in parallel to the switching NMOS transistor Q1′. Therefore, the number of NMOS transistors in the conducting state increases as a bit order of input data increases. This is for the following reason. As shown in the equation (4), the on-resistance of the switching NMOS transistor monotonically increases for the data input value d, but is inversely proportional to a gate width W. By utilizing the above relations, the dependence of the on-resistance on the data input value is reduced. That is to say, by monotonically increasing the number of connected on-resistance correcting NMOS transistors for the data input value d, and by apparently monotonically increasing a channel width W, a rate of increase in on-resistance r_{n(d)} of the switching NMOS transistor is reduced.

On the other hand, since the switching PMOS transistor shows an opposite behavior to the switching NMOS transistor, as a bit order corresponding to a switch circuit increases, the switch circuit includes fewer on-resistance correcting PMOS transistors connected in parallel. Therefore, the number of PMOS transistors in the conducting state decreases as a bit order of input data increases.

Here, the control circuit 1C controls switching of the MOS transistors according to the data input value d as described above.

The following describes operation to control switching of the on-resistance correcting NMOS transistors Q2′ to Q2^{N}−1′ connected in parallel to the switching NMOS transistor Q1′. When the data input value d is “0”, the switching NMOS transistor Q1′ in each of the switch circuits S1 to S2^{N}−1 is switched on, and the switching PMOS transistor Q1 in each of the switch circuits S1 to S2^{N}−1 is switched off. In this case, all the on-resistance correcting NMOS transistors Q2′ to Q2^{N}−1′ connected in parallel to the switching NMOS transistor Q1′ in each of the switch circuits S1 to S2^{N}−1 are switched off.

When the data input value d is “1”, the switching NMOS transistor Q1′ in the switch circuit S1 is switched off, and the switching NMOS transistor Q1′ in each of the switch circuits S2 to S2^{N}−1 is switched on. Also, the switching PMOS transistor Q1 in the switch circuit S1 is switched on, and the switching PMOS transistor Q1 in each of the switch circuits S2 to S2^{N}−1 is switched off. In this case, one on-resistance correcting NMOS transistor, namely the on-resistance correcting NMOS transistor Q2′, connected in parallel to the switching NMOS transistor Q1′ in each of the switch circuits S2 to S2^{N}−1 is switched on, and the on-resistance correcting NMOS transistors Q3′ to Q2^{N}−1′ connected in parallel to the switching NMOS transistor Q1′ in each of the switch circuits S2 to S2^{N}−1 are switched off.

Next, when the data input value d is “2”, the switching NMOS transistor Q1′ in each of the switch circuits S1 and S2 is switched off, and the switching NMOS transistor Q1′ in each of the switch circuits S3 to S2^{N}−1 is switched on. Also, the switching PMOS transistor Q1 in each of the switch circuits S1 and S2 is switched on, and the switching PMOS transistor Q1 in each of the switch circuits S3 to S2^{N}−1 is switched off. In this case, two on-resistance correcting NMOS transistors, namely the on-resistance correcting NMOS transistors Q2′ and Q3′, connected in parallel to the switching NMOS transistor Q1′ in each of the switch circuits S3 to S2^{N}−1 are switched on, and the on-resistance correcting NMOS transistors Q4′ to Q2^{N}−1′ connected in parallel to the switching NMOS transistor Q1′ in each of the switch circuits S3 to S2^{N}−1 are switched off.

Then, when the data input value d is “3”, the switching NMOS transistor Q1′ in each of the switch circuits S1 to S3 is switched off, and the switching NMOS transistor Q1′ in each of the switch circuits S4 to S2^{N}−1 is switched on. Also, the switching PMOS transistor Q1 in each of the switch circuits S1 to S3 is switched on, and the switching PMOS transistor Q1 in each of the switch circuits S4 to S2^{N}−1 is switched off. In this case, three on-resistance correcting NMOS transistors, namely the on-resistance correcting NMOS transistors Q2′ to Q4′, connected in parallel to the switching NMOS transistor Q1′ in each of the switch circuits S4 to S2^{N}−1 are switched on, and the on-resistance correcting NMOS transistors Q5′ to Q2^{N}−1′ connected in parallel to the switching NMOS transistor Q1′ in each of the switch circuits S4 to S2^{N}−1 are switched off.

Hereinafter, as the data input value d increases by one, the number of on-resistance correcting NMOS transistors that are switched on increases by one.

When the data input value d is “2^{N}−1”, the switching NMOS transistor Q1′ in each of the switch circuits S1 to S2^{N}−1 is switched off. Also, the switching PMOS transistor Q1 in each of the switch circuits S1 to S2^{N}−1 is switched on.

Switching of the on-resistance correcting PMOS transistor Q2 to Q2^{N}−1 is controlled in an opposite manner to the switching of the on-resistance correcting NMOS transistors Q2′ to Q2^{N}−1′.

That is to say, when the data input value d is “0”, the on-resistance correcting PMOS transistors Q2 to Q2^{N}−1 connected in parallel to the switching PMOS transistor Q1 in each of the switch circuits S1 to S2^{N}−1 are switched off.

Next, when the data input value d is “1”, 2^{N}−2 on-resistance correcting PMOS transistors, namely the on-resistance correcting PMOS transistors Q2 to Q2^{N}−1, connected in parallel to the switching PMOS transistor Q1 in the switch circuit S1 are switched on.

Then, when the data input value d is “2”, 2^{N}−3 on-resistance correcting PMOS transistors, namely the on-resistance correcting PMOS transistors Q2 to Q2^{N}−2, connected in parallel to the switching PMOS transistor Q1 in each of the switch circuits S1 and S2 are switched on.

Then, when the data input value d is “3”, 2^{N}−4 on-resistance correcting PMOS transistors, namely the on-resistance correcting PMOS transistors Q2 to Q2^{N}−3, connected in parallel to the switching PMOS transistor Q1 in each of the switch circuits S1 to S3 are switched on.

Hereinafter, as the data input value d increases by one, the number of on-resistance correcting PMOS transistors that are switched on decreases by one.

When the data input value d is “2^{N}−1”, all the on-resistance correcting PMOS transistors connected in parallel to the switching PMOS transistor Q1 in each of the switch circuits S1 to S2^{N}−1 are switched off.

In order to precisely control the on-resistance, a gate width of each of the connected on-resistance correcting PMOS transistors Q2 to Q2^{N}−1 and a gate width of each of the on-resistance correcting NMOS transistors Q2′ to Q2^{N}−1′ are respectively made narrower than that of the switching PMOS transistor Q1 and that of the switching NMOS transistor Q1′. Also, a gate length of each of the connected on-resistance correcting PMOS transistors Q2 to Q2^{N}−1 and a gate length of each of the on-resistance correcting NMOS transistors Q2′ to Q2^{N}−1′ are respectively made longer than that of the switching PMOS transistor Q1 and that of the switching NMOS transistor Q1′. In general, the narrower the gate width is, the higher the on-resistance of a MOS transistor is. And, the longer the gate length is, the higher the on-resistance of a MOS transistor is. Therefore, by connecting a MOS transistor having high on-resistance in parallel, the on-resistance is finely adjusted.

With the above-mentioned control method and circuit structure, the on-resistance of the switching NMOS transistor and the on-resistance of the switching PMOS transistor at each stage can be the same for a given data input value d, and thereby reducing the digital-to-analog conversion error.

In the resistive digital-to-analog converter having the above-mentioned first structure in which the on-resistance correcting PMOS transistors Q2 to Q2^{N}−1 are connected in parallel to the switching PMOS transistor Q1, as a bit order corresponding to a switch circuit increases from the switch circuits S1 to S2^{N}−1, the switch circuit includes fewer on-resistance correcting PMOS transistors Q2 to Q2^{N}−1 connected in parallel to the switching PMOS transistor Q1. With this structure, the on-resistance of the switching PMOS transistor Q1 that decreases proportionally for the data input value can be the same as the on-resistance of the switching NMOS transistor Q1′ that increases proportionally for the data input value, thereby sufficiently reducing the digital-to-analog conversion error. In addition, flicker noise in the switching PMOS transistor Q1 is lower than that in the switching NMOS transistor Q1′. Therefore, the resistive digital-to-analog converter having the above-mentioned first structure is higher than a resistive digital-to-analog converter having a second or third structure (described later) in output SNR.

Also, in the resistive digital-to-analog converter having the above-mentioned second structure in which the on-resistance correcting NMOS transistors Q2′ to Q2^{N}−1′ are connected in parallel to the switching NMOS transistor Q1′, as a bit order corresponding to a switch circuit increases from the switch circuits S1 to S2^{N}−1, the switch circuit includes more on-resistance correcting NMOS transistors Q2′ to Q2^{N}−1′ connected in parallel to the switching NMOS transistor Q1′. With this structure, the on-resistance of the switching NMOS transistor Q1′ that increases proportionally for the data input value can be the same as the on-resistance of the switching PMOS transistor Q1 that decreases proportionally for the data input value, thereby sufficiently reducing the digital-to-analog conversion error. In addition, the on-resistance of the switching NMOS transistor Q1′ is lower than that of the switching PMOS transistor Q1. Therefore, the resistive digital-to-analog converter having the second structure can use an on-resistance correcting MOS transistor that is smaller in size than that used by the resistive digital-to-analog converter having the above-mentioned first or the third structure (described later), and thus a circuit area is reduced.

Furthermore, in the resistive digital-to-analog converter having the above-mentioned third structure in which the on-resistance correcting PMOS transistors Q2 to Q2^{N}−1 are connected in parallel to the switching PMOS transistor Q1 and the on-resistance correcting NMOS transistors Q2′ to Q2^{N}−1′ are connected in parallel to the switching NMOS transistor Q1′, as a bit order corresponding to a switch circuit increases from the switch circuits S1 to S2^{N}−1, the switch circuit includes more on-resistance correcting NMOS transistors Q2′ to Q2^{N}−1′ connected in parallel to the switching NMOS transistor Q1′. With this structure, the on-resistance of the switching NMOS transistor Q1′ that increases proportionally for the data input value can be the same as the on-resistance of the switching PMOS transistor Q1 that decreases proportionally for the data input value, thereby sufficiently reducing the digital-to-analog conversion error. In addition, with the combination use of the on-resistance correcting PMOS transistors Q2 to Q2^{N}−1 and the on-resistance correcting NMOS transistors Q2′ to Q2^{N}−1′, the resistive digital-to-analog converter having the third structure corrects the on-resistance more precisely than the resistive digital-to-analog converter having the above-mentioned first or second structure, although the circuit area and the noise increase.

Also, in the resistive digital-to-analog converter having the first structure, for each switch circuit in which the switching PMOS transistor Q1 is switched on when a value of the multi-bit digital input signal indicates the given data, the number of on-resistance correcting PMOS transistors Q2 to Q2^{N}−1 that are switched on is the same.

With this structure, for each switch circuit in which the switching PMOS transistor Q1 is switched on when the value of the multi-bit digital input signal indicates the given data, the combined parallel on-resistance of the switching PMOS transistor Q1 and the on-resistance correcting PMOS transistors Q2 to Q2^{N}−1 connected in parallel to the switching PMOS transistor Q1 can be the same. As a result, the on-resistance is precisely corrected.

Also, in the resistive digital-to-analog converter having the second structure, for each switch circuit in which the switching NMOS transistor Q1′ is switched on when the value of the multi-bit digital input signal indicates the given data, the number of on-resistance correcting NMOS transistors Q2′ to Q2^{N}−1′ that are switched on is the same.

With this structure, for each switch circuit in which the switching NMOS transistor Q1′ is switched on when the value of the multi-bit digital input signal indicates the given data, the combined parallel on-resistance of the switching NMOS transistor Q1′ and the on-resistance correcting NMOS transistors Q2′ to Q2^{N}−1′ connected in parallel to the switching NMOS transistor Q1′ can be the same. As a result, the on-resistance is precisely corrected.

Also, in the resistive digital-to-analog converter having the third structure, for each switch circuit in which the switching PMOS transistor Q1 is switched on when the value of the multi-bit digital input signal indicates the given data, the number of on-resistance correcting PMOS transistors Q2 to Q2^{N}−1 that are switched on is the same. Also, for each switch circuit in which the switching NMOS transistor Q1′ is switched on when the value of the multi-bit digital input signal indicates the given data, the number of on-resistance correcting NMOS transistors Q2′ to Q2^{N}−1′ that are switched on is the same.

With this structure, for each switch circuit in which the switching PMOS transistor Q1 is switched on when the value of the multi-bit digital input signal indicates the given data, the combined parallel on-resistance of the switching PMOS transistor Q1 and the on-resistance correcting PMOS transistors Q2 to Q2^{N}−1 connected in parallel to the switching PMOS transistor Q1 can be the same. Also, for each switch circuit in which the switching NMOS transistor Q1′ is switched on when the value of the multi-bit digital input signal indicates the given data, the combined parallel on-resistance of the switching NMOS transistor Q1′ and the on-resistance correcting NMOS transistors Q2′ to Q2^{N}−1′ connected in parallel to the switching NMOS transistor Q1′ can be the same. As a result, the on-resistance is precisely corrected.

The following describes an embodiment of the present invention, with reference to the drawings.

### Embodiment 1

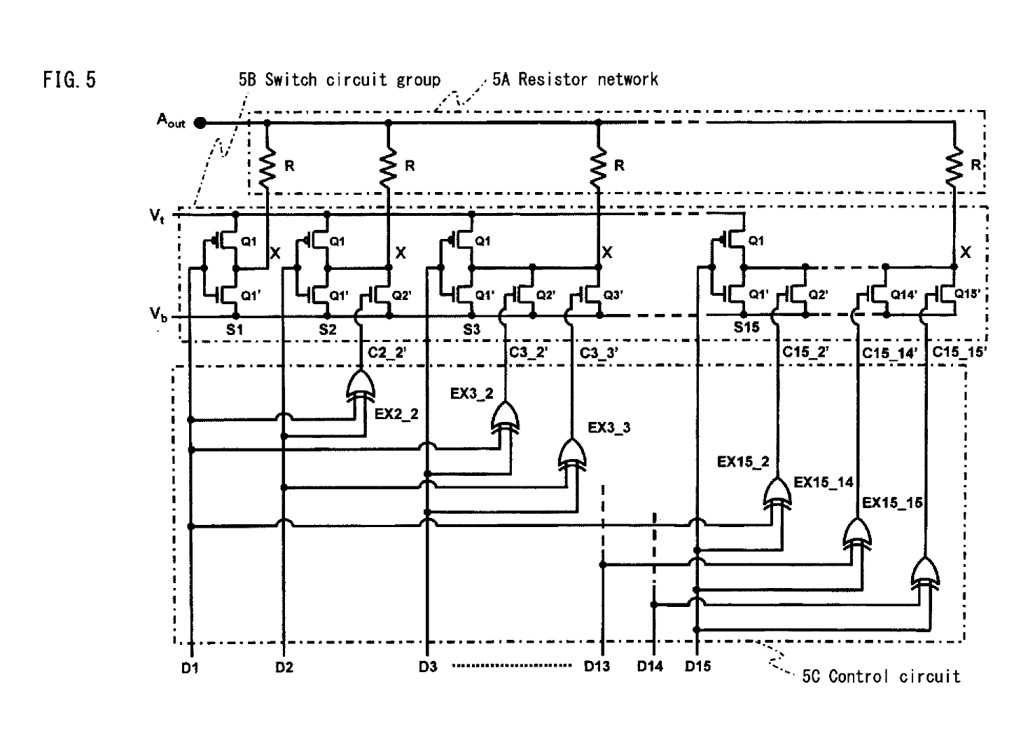

FIG. 5 is a circuit diagram showing a resistive digital-to-analog converter in embodiment 1 of the present invention. The resistive digital-to-analog converter in embodiment 1 is a 4-bit resistive digital-to-analog converter in which the on-resistance of only the switching NMOS transistor is adjusted. The resistive digital-to-analog converter in embodiment 1 includes a resistor network 5A, a switch circuit group 5B, and a control circuit 5C.

The resistor network 5A includes 2⁴−1 resistors R having the same resistance (the resistance is also represented by the reference sign R for the sake of convenience). One end of each of the 2⁴−1 resistors R is connected in common to the analog output terminal Aₒᵤₜ.

The switch circuit group 5B includes 2⁴−1 switch circuits S1 to S15 each including the switching PMOS transistor Q1 and the switching NMOS transistor Q1′, and on-resistance correcting NMOS transistors Q2′ to Q15′ connected in parallel to the switching NMOS transistor Q1′ in each of the switch circuits S2 to S15.

The number of on-resistance correcting NMOS transistors Q2′ to Q15′ added for adjustment increases as the stage increases such that one on-resistance correcting NMOS transistor, namely the on-resistance correcting NMOS transistor Q2′, is connected in the switch circuit S2, and two on-resistance correcting NMOS transistors, namely the on-resistance correcting NMOS transistors Q2′ and Q3′, are connected in the switch circuit S3. One end of each of the 2⁴−1 resistors R included in the resistor network 5A and having the same resistance is connected to an output X of each switch circuit. As described above, the other ends of the resistors R are connected in common to the analog output terminal Aₒᵤₜ.

The control circuit 5C controls switching of the on-resistance correcting NMOS transistors Q2′ to Q15′. The output of EXOR (exclusive or) circuits EX2-2 to EX15-15, i.e. output signals C2_2′ to C15_15′ are input into respective gates of the on-resistance correcting NMOS transistors Q2′ to Q15′. The following describes the generalized input of the EXOR circuit. In a switch circuit Sₐ at the a^{th} stage, the input of the EXOR circuit that outputs an input Cₐ_{_{—}}_{b}′ to a gate of a b^{th} on-resistance correcting NMOS transistor Q_{b}′ is digital input signals Dₐ and D_{b-1}.

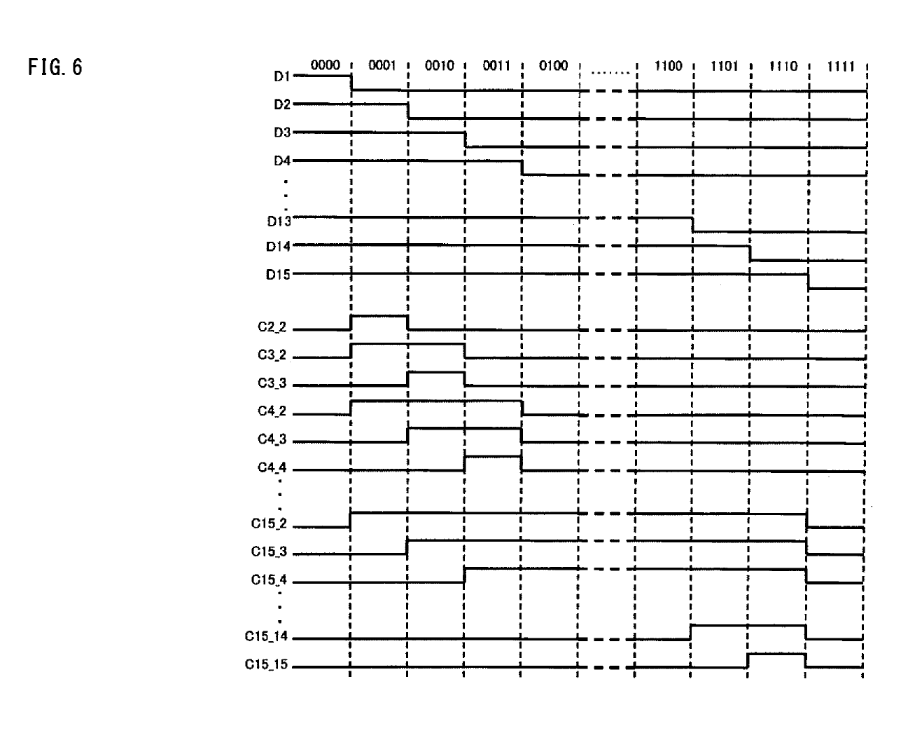

FIG. 6 shows digital input signals D1 to D15 and output signals C2_2′ to C15_15′ of the control circuit 5C when an input bit is increased according to the ramp function. When the output signals C2_2′ to C15_15′ of the control circuit 5C become high, the on-resistance correcting NMOS transistors Q2′ to Q15′ connected in parallel for adjustment are switched into the conducting state.

As for the on-resistance correcting NMOS transistor, when the number of switching MOS transistors that are switched off is 1 and the number of switching NMOS transistors that are switched on is 14 (at a value “0001”), one on-resistance correcting NMOS transistor connected in parallel to each of the switching NMOS transistors that are switched on is switched on. When the number of switching MOS transistors that are switched off is 2 and the number of switching NMOS transistors that are switched on is 13 (at a value “0010”), two on-resistance correcting NMOS transistors connected in parallel to each of the switching NMOS transistors that are switched on are switched on. When the number of switching MOS transistors that are switched off is 3 and the number of switching NMOS transistors that are switched on is 12 (at a value “0011”), three on-resistance correcting NMOS transistors connected in parallel to each of the switching NMOS transistors that are switched on are switched on. Hereinafter, as the number of switching NMOS transistors that are switched on decreases by one, the number of on-resistance correcting NMOS transistors that are switched on and connected in parallel to each of the switching NMOS transistors that are switched on increases by one.

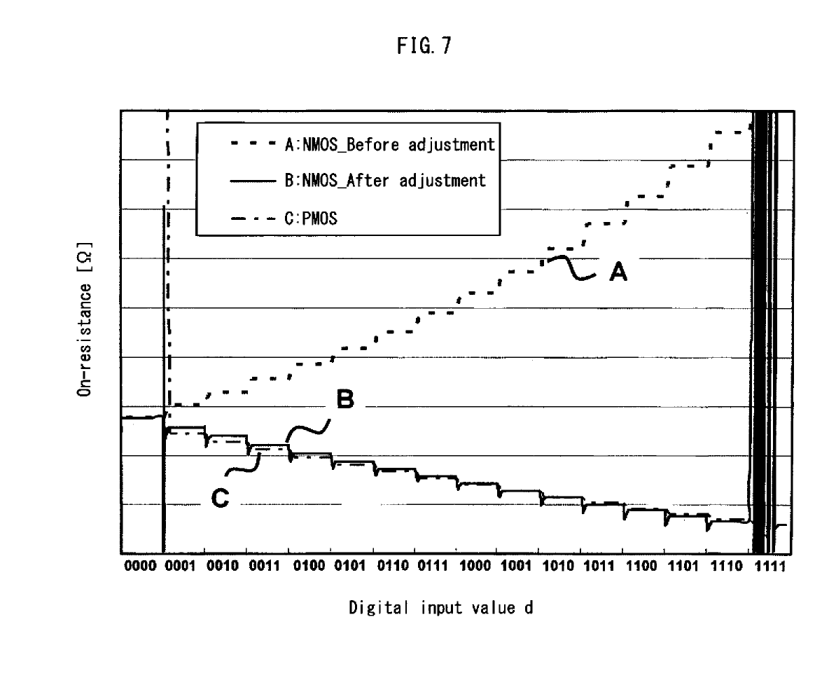

FIG. 7 shows changes of the on-resistance of the PMOS transistor and the NMOS transistor when the digital signals shown in FIG. 6 are input into the digital-to-analog converter shown in FIG. 5. A curve A indicates a change of the on-resistance of the NMOS transistor before adjustment. A curve B indicates a change of the on-resistance of the NMOS transistor after adjustment using the present invention. A curve C indicates a change of the on-resistance of the PMOS transistor. As indicated by the curves A and B, an increase in on-resistance of the NMOS transistor is prevented. Also, as indicated by the curves B and C, the on-resistance of the PMOS transistor and the NMOS transistor is approximately the same for given data input.

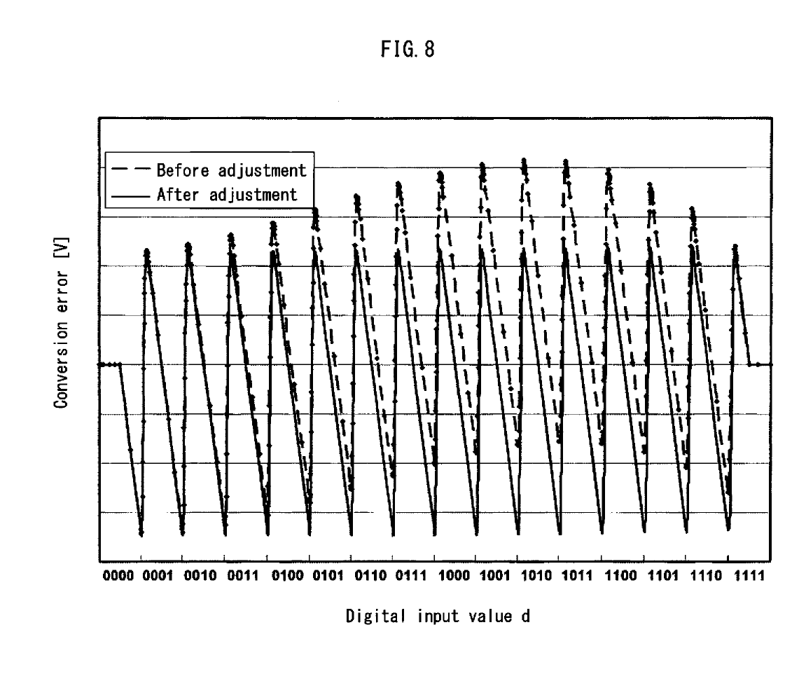

FIG. 8 shows a digital-to-analog conversion error. A solid line indicates the conversion error caused when the digital signals shown in FIG. 6 are input into the digital-to-analog converter shown in FIG. 5. A chain line indicates the conversion error caused before adjustment. As can be seen from FIG. 8, the digital-to-analog conversion error is reduced.

The following describes how to correct the on-resistance changing depending on the value of the multi-bit digital input signal, based on the equation (4). The on-resistance of the MOS transistor changes proportionally depending on an output voltage V_{x(d)} of the switch circuit (inverter). Also, the voltage V_{x(d)} changes approximately proportionally for the data input value d. Therefore, the on-resistance of the MOS transistor changes proportionally for the data input value d.

The on-resistance of the MOS transistor is inverse proportion to the gate width W. Based on the above, by linearly changing the gate width W, the on-resistance of the MOS transistor is controlled so as to linearly change.

Therefore, in the example shown in FIG. 5, by increasing the gate width of the NMOS transistor apparently proportionally for the data input value d, the on-resistance of the NMOS transistor increasing proportionally for the data input value d matches the on-resistance of the PMOS transistor decreasing proportionally for the data input value d.

The effect of the embodiment is described in the explanation about the operation principle.

### INDUSTRIAL APPLICABILITY

The resistive digital-to-analog converter of the present invention provides an effect of reducing a digital-to-analog conversion error caused by a change of the on-resistance of a switching MOS transistor, and is useful for electric equipment that needs to convert a digital signal to an analog signal.

### REFERENCE SIGNS LIST

1A resistor network
1B switch circuit group
1C control circuit
5A resistor network
5B switch circuit group
5C control circuit
Q1 switching PMOS transistor
Q1′ switching NMOS transistor
Q2 to Q2^{N}−1 on-resistance correcting PMOS transistor
Q2′ to Q2^{N}−1′ on-resistance correcting NMOS transistor

1. A resistive digital-to-analog converter that converts a multi-bit digital input signal to an analog signal, comprising:
a resistor network that includes a plurality of resistors having the same resistance and outputs the analog signal from a common connection point to which one end of each of the plurality of resistors is connected in common; and
a switch circuit group that includes a plurality of switch circuits each corresponding to a different one of the plurality of resistors and providing one of a higher reference potential and a lower reference potential for conversion to the other end of the corresponding resistor according to a level of each bit of the multi-bit digital input signal, wherein
each switch circuit includes (i) a first switching MOS transistor that is connected to the other end of the corresponding resistor and a higher reference potential point at one end and the other end thereof, respectively, (ii) a second switching MOS transistor that is connected to the other end of the corresponding resistor and a lower reference potential point at one end and the other end thereof, respectively and (iii) an on-resistance correcting MOS transistor connected in parallel to at least one of the first and second switching MOS transistors such that a change of on-resistance, which occurs with a change of the analog signal caused by a change of the multi-bit digital input signal, is corrected.

2. The resistive digital-to-analog converter of claim 1, wherein
the on-resistance correcting MOS transistor is connected only in parallel to the first switching MOS transistor in each switch circuit, and
the on-resistance correcting MOS transistor is switched on or off according to a value of the multi-bit digital input signal so that, when the value of the multi-bit digital input signal indicates given data, combined parallel on-resistance of the first switching MOS transistor and the on-resistance correcting MOS transistor is equal to on-resistance of the second switching MOS transistor.

3. The resistive digital-to-analog converter of claim 1, wherein
the on-resistance correcting MOS transistor is connected only in parallel to the second switching MOS transistor in each switch circuit, and
the on-resistance correcting MOS transistor is switched on or off according to a value of the multi-bit digital input signal so that, when the value of the multi-bit digital input signal indicates given data, combined parallel on-resistance of the second switching MOS transistor and the on-resistance correcting MOS transistor is equal to on-resistance of the first switching MOS transistor.

4. The resistive digital-to-analog converter of claim 1, wherein
the on-resistance correcting MOS transistor includes a first on-resistance correcting MOS transistor connected in parallel to the first switching MOS transistor in each switch circuit, and a second on-resistance correcting MOS transistor connected in parallel to the second switching MOS transistor in each switch circuit, and
each of the first and second on-resistance correcting MOS transistors is switched on or off according to a value of the multi-bit digital input signal so that, when the value of the multi-bit digital input signal indicates given data, combined parallel on-resistance of the first switching MOS transistor and the first on-resistance correcting MOS transistor is equal to combined parallel on-resistance of the second switching MOS transistor and the second on-resistance correcting MOS transistor.

5. The resistive digital-to-analog converter of claim 2, wherein
as a bit order corresponding to each switch circuit increases, the switch circuit includes fewer on-resistance correcting MOS transistors connected in parallel to the first switching MOS transistor.

6. The resistive digital-to-analog converter of claim 3, wherein
as a bit order corresponding to each switch circuit increases, the switch circuit includes more on-resistance correcting MOS transistors connected in parallel to the second switching MOS transistor.

7. The resistive digital-to-analog converter of claim 4, wherein
as a bit order corresponding to each switch circuit increases, the switch circuit includes fewer first on-resistance correcting MOS transistors connected in parallel to the first switching MOS transistor, and
as a bit order corresponding to each switch circuit increases, the switch circuit includes more second on-resistance correcting MOS transistors connected in parallel to the second switching MOS transistor.

8. The resistive digital-to-analog converter of claim 2, wherein
for each switch circuit in which the first switching MOS transistor is switched on when the value of the multi-bit digital input signal indicates given data, the number of the on-resistance correcting MOS transistors that are switched on is the same.

9. The resistive digital-to-analog converter of claim 3, wherein
for each switch circuit in which the second switching MOS transistor is switched on when the value of the multi-bit digital input signal indicates given data, the number of the on-resistance correcting MOS transistors that are switched on is the same.

10. The resistive digital-to-analog converter of claim 4, wherein
for each switch circuit in which the first switching MOS transistor is switched on when the value of the multi-bit digital input signal indicates given data, the number of the first on-resistance correcting MOS transistors that are switched on is the same, and
for each switch circuit in which the second switching MOS transistor is switched on when the value of the multi-bit digital input signal indicates given data, the number of the second on-resistance correcting MOS transistors that are switched on is the same.

11. The resistive digital-to-analog converter of claim 2, wherein
the on-resistance correcting MOS transistor is longer in channel length than the first switching MOS transistor in each switch circuit.

12. The resistive digital-to-analog converter of claim 3, wherein
the on-resistance correcting MOS transistor is longer in channel length than the second switching MOS transistor in each switch circuit.

13. The resistive digital-to-analog converter of claim 4, wherein
the first on-resistance correcting MOS transistor is longer in channel length than the first switching MOS transistor in each switch circuit, and
the second on-resistance correcting MOS transistor is longer in channel length than the second switching MOS transistor in each switch circuit.
